(19) United States
(12) Patent Application Publication
(10) Pub. No.: US 2002/0052083 A1
(43) Pub. Date: May 2, 2002

(54) Cost effective split-gate process that can independently optimize the low voltage(LV) and high voltage (HV) transistors to minimize reverse short channel effects

(76) Inventors: Xin Zhang, Plano, TX (US); Douglas T. Grider, McKinney, TX (US); Jarvis B. Jacobs, Richardson, TX (US); Howard L. Tigelaar, Allen, TX (US)

Correspondence Address: TEXAS INSTRUMENTS INCORPORATED, P O BOX 655474, M/S 3999, DALLAS, TX, 75265

(21) Appl. No.: 09/971,198

(22) Filed: Oct. 4, 2001

Related U.S. Application Data
(60) Provisional application No. 60/243,773, filed on Oct. 26, 2000.

(51) Int. Cl. H01L 21/8234

(52) U.S. Cl. 438/275

(57) ABSTRACT

A method of forming LV and HV transistors with independently optimized threshold adjust (Vt) implants to minimize reverse short channel effects. A through-the-poly implant is used for the Vt implants after gate (214) formation. The Vt implants for the LV transistors (224,226) are performed after the LDD patterns (216,238). The Vt implants for the HV transistors (220, 222) are performed after the I/O LDD patterns (234,244).

### FIELD OF THE INVENTION

The invention is generally related to the field of semiconductor processing of dual voltage integrated circuits.

### BACKGROUND OF THE INVENTION

In the field of semiconductor devices, it is sometimes desirable to combine high performance, low voltage (LV) core transistors with high voltage (HV) input/output (I/O) transistors. The LV and HV refers to the operating voltage of the transistors. The operating voltages decrease as the semiconductor technology continues to shrink. For example, the LV transistors may have an operating voltage of 1.8V, 1.5V, or 1.2V while the HV transistors may have an operating voltage of 3.3V, 1.8V, or 1.5V, respectively.

A split-gate process may be used to form dual voltage integrated circuits (IC's). In a split-gate process, the gate dielectric is thicker for the HV transistors than it is for the LV transistors. In addition, separate masking levels are used to form the drain extension regions for the LV and HV transistors. A NLDD mask is used to form pocket regions and drain extension regions in the n-type LV transistors and mask these implants from the I/O (HV) transistors and the p-type LV transistors. An I/O NLDD pattern is then used to form drain extension regions (but no pockets) in the HV transistors. PLDD and I/O PLDD masks are then required for the p-type LV and HV transistors.

To remain competitive in today's semiconductor market, companies are under constant pressure to reduce the manufacturing costs. One means of significantly reducing this cost is by eliminating mask levels. Each mask level incorporates a number of steps such as resist coating, exposure, development, alignment check and then several clean-up steps (resist ash, resist strip, megasonic clean). Each mask eliminated can result in considerable reduction in manufacturing cost and improve profit margin.

### SUMMARY OF THE INVENTION

The invention is a method of forming LV and HV transistors with independently optimized threshold adjust (Vt) implants to minimize reverse short channel effects. A through-the-poly implant is used for the Vt implants. The Vt implants for the LV transistors are performed after the LDD patterns (e.g., NLDD and PLDD). The Vt implants for the HV transistors are performed after the I/O LDD patterns (e.g., I/O NLDD and I/O PLDD).

An advantage of the invention is providing a method of forming LV and HV transistors with minimized reverse short channel effects and no additional masking levels.

This and other advantages will be apparent to those of ordinary skill in the art having reference to the specification in conjunction with the drawings.

### BRIEF DESCRIPTION OF THE DRAWINGS

In the drawings:

FIG. 1 is a block diagram of the process flow for accomplishing an embodiment of the invention; and

FIGS. 2A-2G are cross-sectional diagrams of LV and HV transistors formed according to the process of FIG. 1 at various stages of fabrication.

### DETAILED DESCRIPTION OF THE EMBODIMENTS

The invention will now be described in conjunction with a split-gate CMOS process. It will be apparent to those of ordinary skill in the art having reference to the specification that the invention may be applied to other processes in which it is desired to optimize the Vt implants for separate transistor types.

In a typical split-gate CMOS process, both the core (LV) transistors and the I/O (HV) transistors share the same Vt implant. Because the I/O transistor has a thicker gate oxide, the Vt implant is set to meet the I/O transistor Vt specifications. As core transistor gate lengths shrink, I/O transistor gate lengths usually stay at the previous level. Therefore, the Vt implant also stays at the previous level.

In order to meet the core transistor I_{eff} specification, pocket implants increase due to the long channel Vt is set by the Vt implant, (i.e., pocket implants do not impact long channel Vts significantly). The core nominal transistors have a much higher Vt than the long channel transistors. This is not good for analog design.

One way to reduce the reverse short channel effect (nominal transistor having higher Vt than long channel transistor) is to add two pattern levels. The first pattern level separates the LV Vtn implant and the HV Vtn implant. The second pattern level separates the LV Vtp and HV Vtp implants. In this case, the Vt implant for the core (LV) transistor can be separately optimized with the pocket implant to reduce the reverse short channel effect.

Unfortunately, adding masking levels is expensive. The invention provides a way to separately optimize the Vt implants without adding additional masking steps. The Vt implants are moved to later in the process after the gates have been formed. A through-the poly implant is used for the Vt implants after the respective LDD patterns. Advantages of moving the Vt implants later in the process after the gates are formed are that no dopant is lost during the gate oxidation as is the case in normal processing and also the Vt dopant profile is not degraded by multiple thermal cycles as in prior art. Both of these factors result in improved short channel behavior.

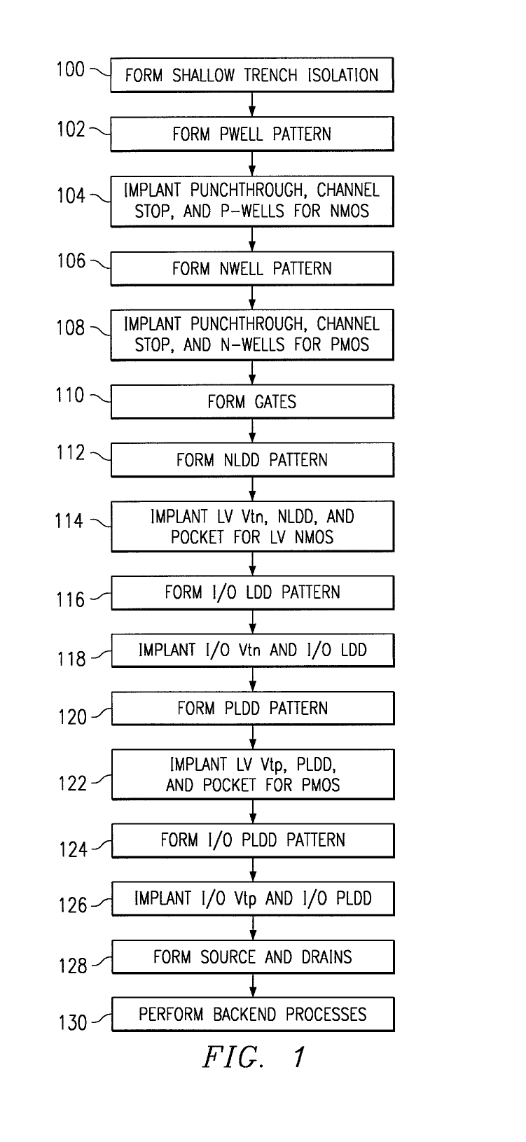

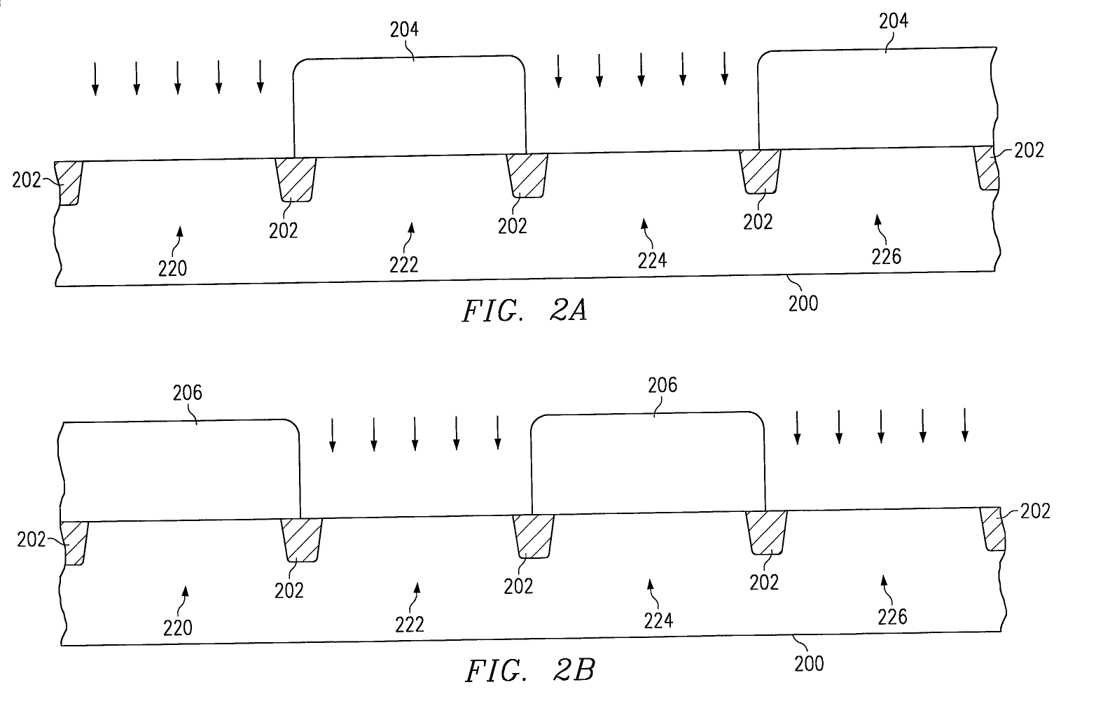

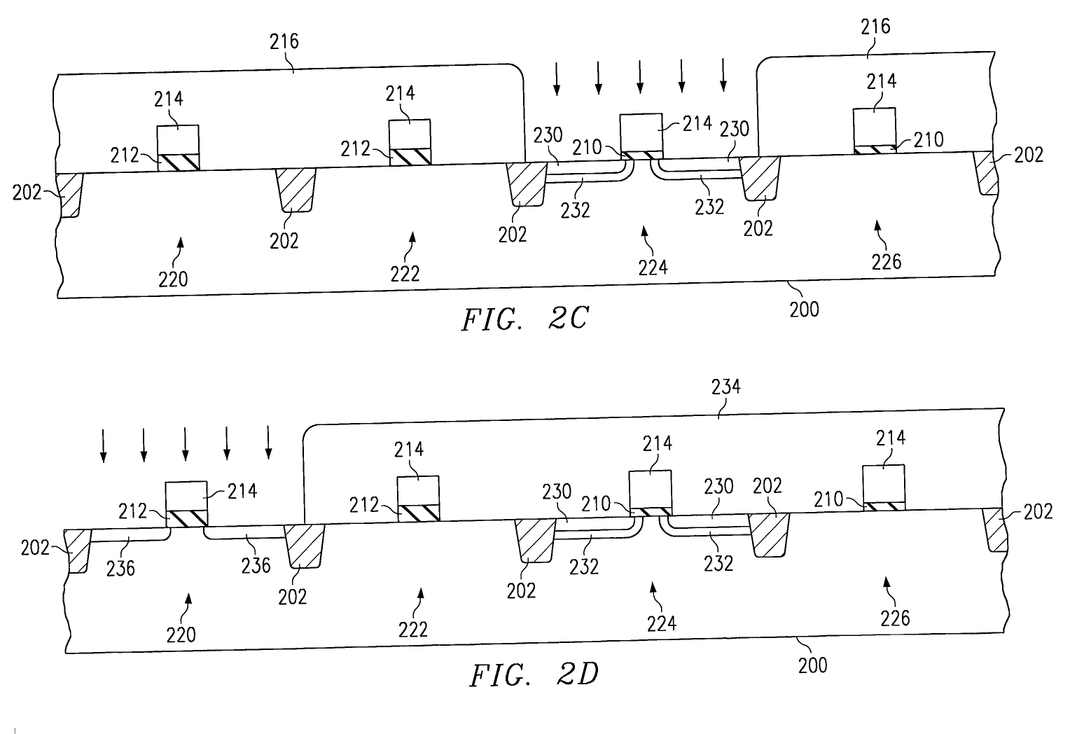

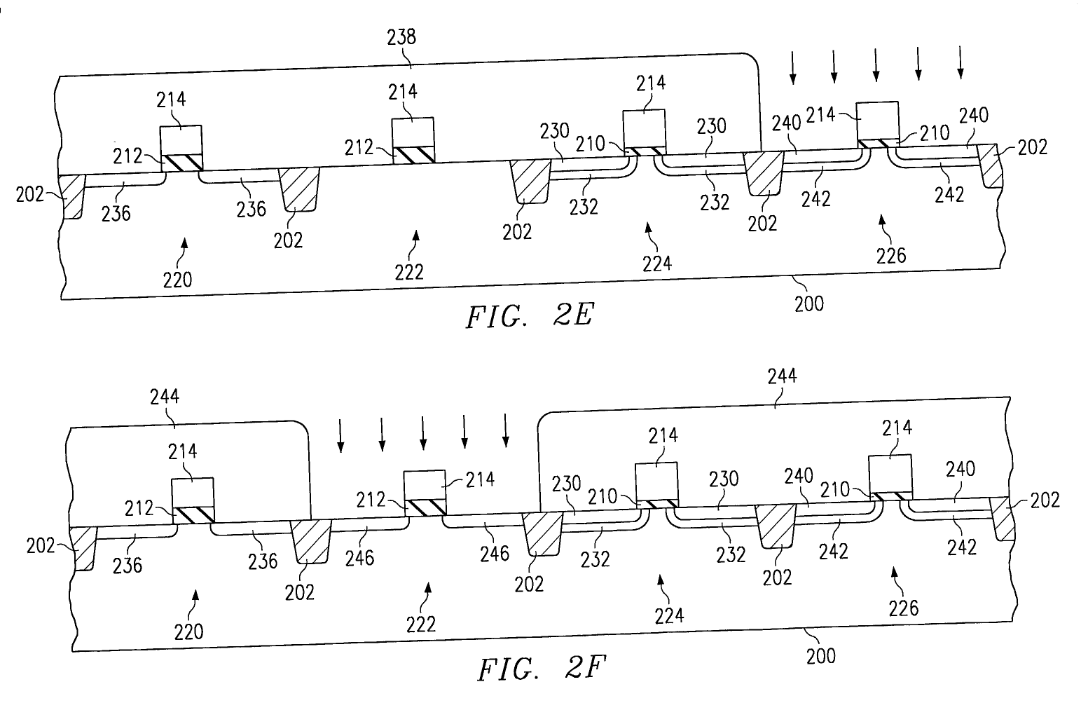

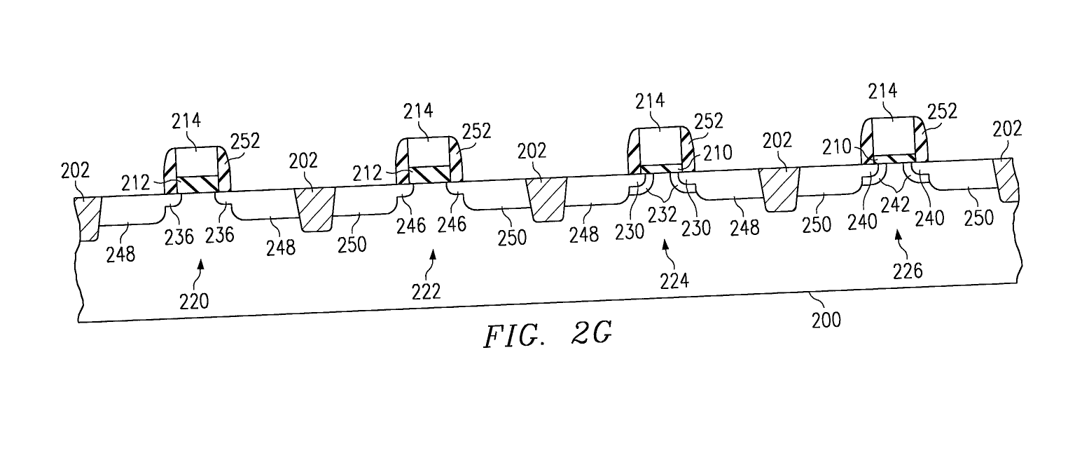

A process according to an embodiment of the invention is shown in FIG. 1. Cross-sections of a semiconductor body 200 at various stages of the process of FIG. 1 are shown in FIGS. 2A-2G. Referring to FIG. 2A and Step 100 of FIG. 1, shallow trench isolation (STI) structures 202 are formed in semiconductor body 200. Semiconductor body 200 is typically a silicon substrate with or without epitaxial layers formed thereon. However, it will be apparent to those of ordinary skill in the art that other substrate materials, such as SiGe, may alternatively be used. Various methods for forming STI structures 202 are known in the art.

Next, a pattern 204 is formed over semiconductor body 200. Pattern 204 may be a standard Pwell pattern. The Vtn implant is not performed at this time. It is used to block the p-type channel stop, p-type punchthrough and/or p-type well implants from the regions (e.g., 222 and 226) where p-type (PMOS) transistors will be formed. Using Pwell pattern 204, the p-type channel stop, p-type punchthrough and/or p-type well implants are performed to implant the NMOS regions (e.g., 220 and 224) where n-type (NMOS) transistors are to be formed. As an example, the following implant doses and energies may be used:

P-type punchthrough implant: a few e12 boron at 50 to 70 kev;

P-type channel stop implant: 8e12 boron at 140 kev; and

Pwell implant: 3.5e13 boron at 375 kev.

After the desired implants, Pwell pattern 204 is removed.

Referring to FIG. 2B, a pattern 206 is formed over semiconductor body 200. Pattern 206 may be a standard Nwell pattern. The Vtp implant is not performed at this time. It is used to block the n-type channel stop, n-type punchthrough and/or n-type well implants from the NMOS regions (e.g., 220 and 224) where n-type (NMOS) transistors will be formed. Using Nwell pattern 206, the n-type channel stop, n-type punchthrough and/or n-type well implants are performed to implant the PMOS regions (e.g., 222 and 226) where p-type (PMOS) transistors are to be formed. As an example, the following implant doses and energies may be used:

N-type punchthrough implant: a few e12 phos at 150 kev;

N-type channel stop implant: 4e12 phos at 320 kev; and

Nwell implant: 4.0e13 phos at 675 kev.

After the desired implants, Nwell pattern 206 is removed.

Next, the gate dielectrics 210, 212 and gate electrodes 214 are formed. Various methods for forming gate electrodes 214 and dielectrics 210, 212 are known in the art. Typically, the gate dielectrics 212, 210 comprise silicon dioxide. Gate dielectric 212, for the HV or 110 transistors, is typically thicker that gate dielectric 210 for the LV transistors. The gate electrodes 214 typically comprise polysilicon.

Referring to FIG. 2C, an NLDD pattern 216 is formed over semiconductor body 200 and gates 214. NLDD pattern 216 exposes the LV NMOS region 224 where n-type LV (core) transistors are to be formed. Regions 220, 222, and 226 for the I/O transistors (NMOS and PMOS) and the LV PMOS transistors are masked by NLDD pattern 216. Using NLDD pattern 216, the NLDD regions 230 (using n-type dopant) and pocket regions 232 (using p-type dopant) are implanted.

As an example, the implant dose and energy may be as follows:

NLDD implant: 6e14 Arsenic at 9 kev; and

p-type pocket: 2.4e13 boron at 15 kev 20 deg.

According to the invention, the LV Vtn implant is performed at this point using the NLDD pattern 216. The LV Vtn implant is performed through the polysilicon of gate electrode 214. Because of this, a higher implant energy needs to be used. For example, boron may be implanted at a dose of 5e12 and an energy of 80 kev KeV. Because the LV Vtn is performed separately from the I/O Vtn, each implant may be independently optimized. Furthermore, because the Vtn implant is later in the process after gate processing none of the dopant is lost during gate oxidation and the dopant profiles are less degraded because they see fewer thermal processing steps. Reducing the thermal cycle changes the way dopant piles up at the surface and allows the dopant to be more local (less diffusion). Both of these factors reduce the reverse short channel effects.

After removing the NLDD a pattern 216, an I/O NLDD pattern 234 is formed, as shown in FIG. 2D. I/O NLDD pattern 234 exposes the HV NMOS region 220 where NMOS I/O transistors will be formed. Regions 222, 224, and 226 for the PMOS I/O transistors and the LV transistors are covered. The I/O LDD implant is then performed to form I/O NLDD regions 236. As an example, the following implant dose and energy may be used for the I/O LDD:

Phos: 5e13 at 60 kev; and

Arsenic: 5e13 at 80 kev.

Pocket regions are not typically used for the I/O transistors. The I/O Vtn implant is also performed at this time. The I/O Vtn implant is a through-poly implant and thus requires a higher implant energy. For example, boron may be implanted at a dose of 2e12 and an energy of 80 KeV. Performing the I/O Vtn implant later in the process and separately from the LV Vtn implant improves the reverse short channel effects. After removing I/O NLDD pattern 234, the process is repeated for the PMOS transistors if desired. A PLDD pattern 238 is formed over the semiconductor body 200 as shown in FIG. 2E. PLDD pattern 238 exposes LV PMOS region 226 where the LV PMOS transistors are to be formed. Regions 220, 222, and 224 for the I/O transistors and NMOS LV transistors are covered. Using PLDD pattern 238, the PLDD regions 240 (using p-type dopant) and pocket regions 242 (using n-type dopant) are implanted. As an example, the following implant dose and energy may be used:

PLDD implant: 6.0e14 BF2 at 8 kev; and

n-type pocket implant: 9.2e13 phos at 40 kev, 20 deg.

According to the invention, the LV Vtp implant is performed at this point using the PLDD pattern 238. The LV Vtp implant is performed through the polysilicon of gate electrode 214. Because of this, a higher implant energy needs to be used. For example, phosphorus may be implanted at a dose of 5e12 and an energy of 190 KeV. Because the LV Vtp is performed separately from the I/O Vtp, each implant may be independently optimized. Furthermore, because the Vtp implant is later in the process after gate processing none of the dopant is lost during gate oxidation and the dopant profiles are less degraded because they see fewer thermal processing steps. Reducing the thermal cycle changes the way dopant piles up at the surface and allows the dopant to be more local (less diffusion). Both of these factors reduce the reverse short channel effects.

After removing the PLDD a pattern 238, an I/O PLDD pattern 244 is formed, as shown in FIG. 2F. I/O PLDD pattern 244 exposes the HV PMOS region 222 where PMOS I/O transistors will be formed. Regions 220, 224, and 226 for the NMOS I/O transistors and the LV transistors are covered. The I/O PLDD implant is then performed to form I/O PLDD regions 246. As an example, the implant dose may be on the order of 3.5e13 boron with an energy of 20 kev.

Pocket regions are not typically used for the I/O transistors. The I/O Vtp implant is also performed at this time. The I/O Vtp implant is a through-poly implant and thus requires a higher implant energy. For example, phosphorus may be implanted at a dose of 3e12 and an energy of 190 KeV. Performing the I/O Vt implant later in the process and separately from the LV Vtp implant improves the reverse short channel effects. The I/O PLDD pattern 244 is then removed.

Referring the FIG. 2G, the sidewall spacers 252 and then the source/drain regions 248 (n-type) and 250 (p-type) are formed. Methods for forming the sidewall spacers 252 and source/drain regions 248 and 250 are known in the art. Example S/D implant dose and range are:

NSD: 1.5e15 arsenic at 70 kev and 1.5e14 phos at 50 kev

PSD: 2.7e15 boron at 7 kev

Processing then continues with backend processing to form interconnect levels and packaging.

While this invention has been described with reference to illustrative embodiments, this description is not intended to be construed in a limiting sense. Various modifications and combinations of the illustrative embodiments, as well as other embodiments of the invention such as altering the order of the LDD pattern levels and implants, will be apparent to persons skilled in the art upon reference to the description. It is therefore intended that the appended claims encompass any such modifications or embodiments.

In the claims:

1. A method of fabricating an integrated circuit having a low voltage transistor and a high voltage transistor, comprising the steps of:
forming a first gate electrode over a semiconductor body in a low voltage region and forming a second gate electrode over the semiconductor body in a high voltage region; then
forming a first pattern to cover said high voltage region and expose said low voltage region;
implanting an LDD region in said low voltage region;
performing a first threshold adjust implant through said first gate electrode using said first pattern;
removing said first pattern;
forming a second pattern to expose said high voltage region and cover said low voltage region;
implanting an I/O LDD region in said high voltage region;
performing a second threshold adjust through said second gate electrode using said second pattern; and
removing said second pattern.

2. The method of claim 1, further comprising the step of implanting a pocket region in said low voltage region using said first pattern.

3. The method of claim 1, wherein said low voltage transistor is a low voltage NMOS transistor and said high voltage transistor is a high voltage NMOS transistor, and further comprising the steps of:
forming a PLDD pattern to cover said high voltage NMOS transistor and said low voltage NMOS transistor and expose a low voltage PMOS region;
implanting a PLDD region in said low voltage PMOS region;
performing a third threshold adjust implant using said PLDD pattern;
removing said PLDD pattern;
forming a I/O PLDD pattern to cover said low voltage NMOS transistor, said low voltage PMOS region, and said high voltage NMOS transistors, and expose a high voltage PMOS region;
implanting an I/O PLDD region in said high voltage PMOS region;
performing a fourth threshold adjust using said I/O PLDD pattern; and
removing said I/O PLDD pattern.

4. The method of claim 1, further comprising the step of performing a channel stop implant prior to forming said gate electrode.

5. The method of claim 1, further comprising the step of performing a punchthrough implant prior to forming said gate electrode.

6. The method of claim 1, further comprising the step of performing a well implant prior to forming said gate electrode.

7. A method of fabricating an integrated circuit having low voltage NMOS transistors, low voltage PMOS transistors, high voltage NMOS transistors and high voltage PMOS transistors, comprising the steps of:
forming first gate electrodes over the semiconductor body in a low voltage NMOS region, forming second gate electrodes over the semiconductor body in a high voltage NMOS region, forming third gate electrodes over the semiconductor body in a low voltage PMOS transistor region, and forming fourth gate electrodes over the semiconductor body in a high voltage PMOS region; then
forming a NLDD pattern to cover said high voltage NMOS region, said high voltage PMOS region and said low voltage PMOS region and expose said low voltage NMOS region;
implanting an NLDD region in said low voltage NMOS region;
performing a first threshold adjust implant through said first gate electrodes using said NLDD pattern;
removing said NLDD pattern;
forming a I/O NLDD pattern to expose said high voltage NMOS region and cover said low voltage NMOS region, said low voltage PMOS region and said high voltage PMOS region;
implanting an I/O NLDD region in said high voltage NMOS region;
performing a second threshold adjust through said second gate electrodes using said I/O NLDD pattern; and
removing said I/O NLDD pattern.

8. The method of claim 7, further comprising the steps of:
implanting a first pocket region in said low voltage NMOS region using said NLDD pattern.

9. The method of claim 7, further comprising the steps of:
forming a PLDD pattern to cover said high voltage NMOS region, high voltage PMOS region and said low voltage NMOS region and expose said low voltage PMOS region;
implanting a PLDD region in said low voltage PMOS region;
performing a third threshold adjust implant using said PLDD pattern;
removing said PLDD pattern;
forming a I/O PLDD pattern to cover said high voltage NMOS region, said low voltage NMOS region and said low voltage PMOS region and expose a high voltage PMOS region;
implanting an I/O PLDD region in said high voltage PMOS region;
performing a fourth threshold adjust using said I/O PLDD pattern; and
removing said I/O PLDD pattern.

10. The method of claim 7, further comprising the steps of:
performing a masked n-type channel stop implant prior to forming said first gate electrodes; and
performing a masked p-type channel stop implant prior to forming said first gate electrodes.

11. The method of claim 7, further comprising the steps of:
performing a masked n-type punchthrough implant prior to forming said first gate electrodes; and
performing a masked p-type punchthrough implant prior to forming said first gate electrodes.

12. The method of claim 7, further comprising the steps of:
performing a masked p-type well implant prior to forming said first gate electrodes; and
performing a masked n-type well implant prior to forming said first gate electrodes.
